(19) United States
(12) Patent Application Publication
(10) Pub. No.: US 2013/0069675 A1
(43) Pub. Date: Mar. 21, 2013

(54) CONDUCTIVE FLUID LEAK DETECTOR

(71) Applicant: JOHN L. WOLOSZYK, Waterford, WI (US)

(72) Inventor: JOHN L. WOLOSZYK, Waterford, WI (US)

(73) Assignee: Dorlen Products, Inc., Greenfield, WI (US)

(21) Appl. No.: 13/426,781

(22) Filed: Mar. 22, 2012

Related U.S. Application Data
(60) Provisional application No. 61/467,572, filed on Mar. 25, 2011.

(51) Int. Cl. G01R 27/22

(52) U.S. Cl. CPC G01R 27/22
USPC 324/693

(57) ABSTRACT

A conductive fluid leak detector having an enclosed and secure housing is disclosed. The housing as well as a pair of conductive fluid sensing probes that project through the housing are tamper-resistant. The detector is provided with a switch for activation of a wash down mode which allows cleaning of the environment where the detector is installed without triggering an alarm. Upon activating the switch, the detector is deactivated for a predetermined period of time. The conductive fluid leak detector is coupled to an external maintenance or alarm system. When not deactivated or in the wash down mode, the detector sends a signal to the external system when conductive fluid is detected by the sensing probes.

### RELATED APPLICATIONS

This application claims the benefit of co-pending U.S. Provisional Patent Application Ser. No. 61/467,572, filed 25 Mar. 2011.

### BACKGROUND OF THE INVENTION

The present invention relates to conductive fluid leak detection and specifically to a detector that can be installed in environments that require periodic cleaning and that may be subject to vandalism and abuse such as public restroom facilities. The invention is also suitable for use in institutional kitchens, industrial manufacturing plants, laboratories and clean rooms.

Any equipment that utilizes conductive fluid, such as water has the potential to malfunction which may result in a conductive fluid leak. In addition, the pipes or conduits that supply conductive fluid to the equipment may also be susceptible to damage or wear which similarly results in a conductive fluid leak. If unnoticed or unchecked, such leaks often lead to extensive property damage. Every year, millions of dollars are spent repairing or remediating facilities damaged by conductive fluid leaks, such as water leaks. Often times, the resulting damage from a leak can be mitigated or eliminated had the property manager or owner been timely made aware of the leak.

There are devices and systems available on the market to perform this function. See, for example, U.S. Pat. Nos. 6,147,613; 6,367,096; 6,369,714 and 7,549,435. However, these devices and systems are typically overly complex, require the placement and maintenance of delicate sensors, or are often the target of abuse or vandalism by those that discover the presence of the device. In addition, many environments where a conductive fluid leak detector is desired are also environments which need to be cleaned on a regular basis. The cleaning process can trigger a “false alarm” by the detector. Once a detector or system provides repeated “false alarms” its effectiveness is called into question and future alarms may be simply ignored. Similarly, detectors with fragile components that are subject to abuse and/or vandalism are often rendered inoperable and thus do not perform the detecting function for which they were installed. Complex detectors and systems must often be installed when the environment where they reside is built. Often, post-construction installation processes are overly complicated and costly. All of these factors present shortcomings in the field of conductive fluid detection.

Accordingly, there is a need for a conductive fluid leak detector that is economical, reliable, allows for periodic cleaning of the environment where installed without sending a false alarm, tamper-resistant, and easily installed where needed. The present invention seeks to overcome the shortcomings in the prior art by providing a conductive fluid detector that meets these objectives.

### SUMMARY OF THE INVENTION

The present invention provides a conductive fluid leak detector that is suitable for use in areas of a building that require frequent cleaning such as public and employee restrooms, commercial kitchens and industrial manufacturing facilities. In one embodiment, the detector includes a housing, at least one fluid sensing probe, a fluid sensing circuit, a switch and a power supply. The fluid sensing circuit further includes a timer whereby when the switch is touched or activated, the fluid sensing circuit is deactivated for a predetermined period of time. The timer and predetermined period of time can be adjusted or varied. In another embodiment, the fluid detecting circuit of the detector has an activation mode and a deactivation mode. In the activation mode, the detector senses for the presence of a conductive fluid at the probe or probes. In the deactivation mode, the detector does not sense for the presence of fluid. The detector changes from the activation mode to the deactivation mode by means of the switch. The duration or length of the deactivation mode is controlled by the timer. In the activation mode and upon sensing the presence of a conductive fluid, the detector output sends an output signal to a remote location.

Thus, the present invention has a mode of operation to allow cleaning without activating the conductive fluid leak detector. The external switch, typically located on the detector housing is activated by cleaning personnel prior to cleaning. Once activated, the conductive fluid leak detector circuit within the detector housing is disabled or deactivated for a predetermined time period. The length of time can be adjusted. Typically, the time period is set at installation but can be changed after installation if necessary. Once the predetermined time period has lapsed, the conductive fluid detecting circuitry is again enabled (or re-activated) and the detector resumes sensing for conductive fluid within the proximity of the probe or probes.

Another feature of the present invention is its vandal resistant construction. All external components of the invention are of robust design. The detector's circuitry is located within a secure housing, such as an extra heavy duty powder coated aluminum housing. A removable cover is secured to the housing with vandal resistant screws. The conductive fluid sensing probes that extend through the housing are securely affixed to the housing and of strong construction. Ideally they are fabricated from stainless steel. The external switch is preferably a piezo electronic switch which has no moving parts. Like the probes, the switch is fabricated from stainless steel too. The cover, the probes and the switch are sealed to the housing so that no conductive fluid or other contaminants can pass into the housing. The entire device is also nondescript; it would not be readily apparent to an occupant of the environment where the device is installed that the device is in fact a conductive fluid leak detector.

Once the presence of conductive fluid is sensed by the device, the detector sends a signal to an alarm system, security system, building management system or monitoring system to trigger an alarm. In addition, a signal may be sent to a remote power relay that in turn controls an electronic conductive fluid shut off valve. Alternatively, the detector may be coupled to a specific monitoring panel, such as the 2100 Series monitoring panel manufactured by Dorlen Products, Inc., Milwaukee, Wis. By utilizing this panel (or an equivalent thereof) a user can test the detector from the panel to insure the detector is working properly.

Common conductive fluids include water, coolants, cleaning solutions and other liquids. This list is not intended to be limiting and conductive fluids is hereby defined to include other fluids as well.

### BRIEF DESCRIPTION OF THE DRAWINGS

FIG. 1 is a perspective view of the conductive fluid leak detector with the cover secured in place;

FIG. 2 is a top plan view of the detector with the cover removed;

FIG. 3 depicts the installation and application of the detector in detecting a conductive fluid overflow condition triggered by a malfunctioning urinal;

FIG. 4 depicts the detector coupled to a power supply and monitoring panel;

FIG. 5 is a schematic diagram of a first circuit utilized in the conductive fluid leak detector; and

FIG. 6 is a schematic diagram of a second circuit utilized in the conductive fluid leak detector.

### DESCRIPTION OF THE PREFERRED EMBODIMENT

Although the disclosure hereof is detailed and exact to enable those skilled in the art to practice the invention, the physical embodiments herein disclosed merely exemplify the invention which may be embodied in other specific structures. While the preferred embodiment has been described, the details may be changed without departing from the invention.

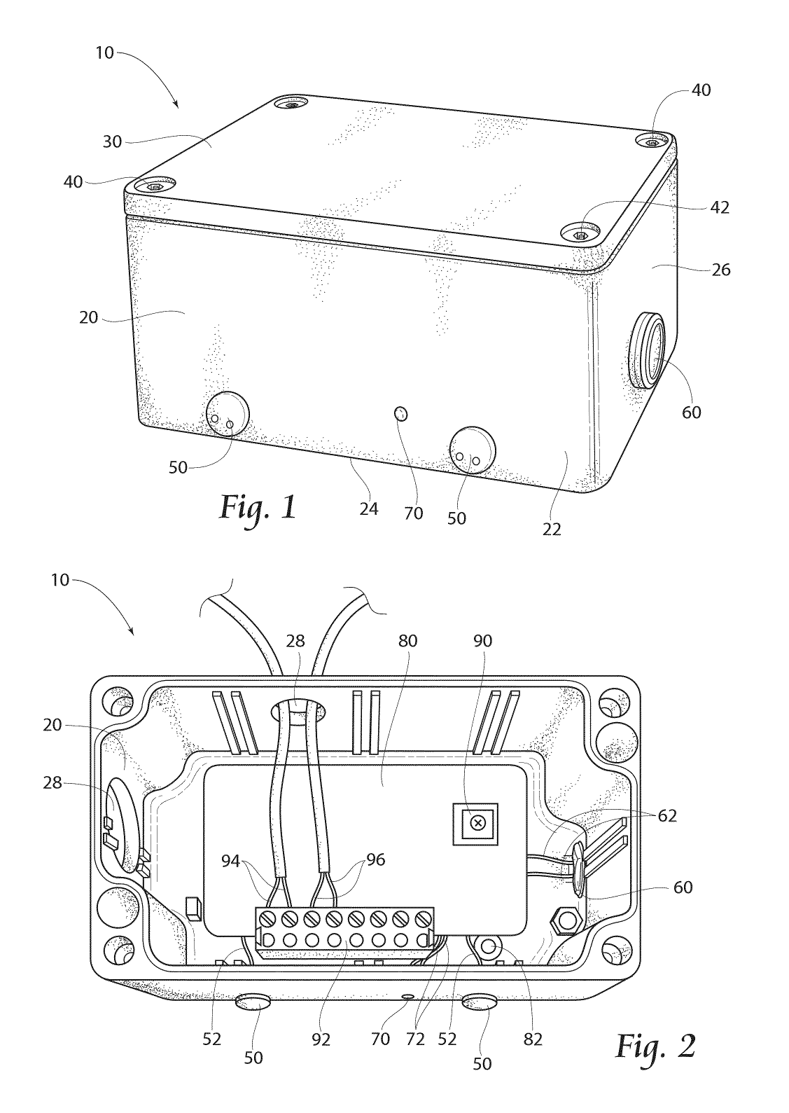

As shown in FIG. 1, the conductive fluid leak detector is shown generally at reference numeral 10. A housing 20 having a removable cover 30 is also shown. The housing 20 is of solid construction so as to be tamper and vandal resistant. Preferably, the housing is made from extra heavy duty powder coated aluminum or a similarly durable material. The cover 30, which may be made from the same material, is secured to the housing with tamper-resistant screws 40. Each screw 40 has a unique head 42 which requires a special tool (not shown) to remove the screw. Absent inserting the special tool into the screw head, one cannot remove the cover to gain access to the circuitry and timer within the housing 20 or to remove the detector 10 from the installation location where it has been secured.

A pair of conductive fluid sensing probes 50 is located on a side 22 of housing 20 near its lower edge 24. The probes 50 could be mounted to other and/or different sides of the housing 20 as well. Each probe 50 is preferably made from stainless steel and is coupled to the circuitry described below with a wire 52. Like the housing 20 and cover 30, the probes 50 are similarly tamper and vandal resistant. The probes 50, like the detector, are also nondescript so that it would not be readily apparent to a person in the vicinity of the device 10 that the function of the probes 50 is to sense the presence of conductive fluid.

A switch 60 is also located on a side 26 of the housing 20. In a preferred embodiment, the switch 60 is a piezo electronic switch that has no moving parts and is conductive fluid resistant. Other switches could also be utilized. The switch 60 is similarly coupled to the circuit 80 by wires 62 within the housing 20. The switch 60 is activated by cleaning personnel to start the inactivation or wash down mode of the device 10. During the wash down mode, the detector 10 will not send an alarm signal (output) to the monitoring system or other device to which it is connected, despite the fact that the sensors 50 detect the presence of a conductive fluid.

A visual indicator 70 may also be located on the exterior of the housing 20, for example in side 22 as shown in FIG. 1. In the preferred embodiment, the indicator is a LED light. The LED light 70 has a low profile and is sealed to the housing 20 so that no conductive fluid or contaminates can pass into the housing 20. Also coupled to the circuit 80 by wires 72, the indicator 70 preferably illuminates in two conditions. The first is to confirm the switch 60 has been activated and the second is to indicate that an alarm has been triggered. Once the wash down mode has been activated, the LED light 70 will remain illuminated for the preset and predetermined wash down mode time period. Once the time period has expired, the LED light 70 will no longer be illuminated and the device 10 will resume its sensing function. When the device 10 is not in the wash down mode and the device senses the presence of a conductive fluid, the LED light 70 will illuminate to indicate that an alarm event has been detected and an output has been sent by the device 10. Preferably, the color of the LED 70 is different for each indication. For example, a green light within the LED 70 may represent the device 10 is in the wash down mode and a red light may indicate an alarm has been triggered and sent.

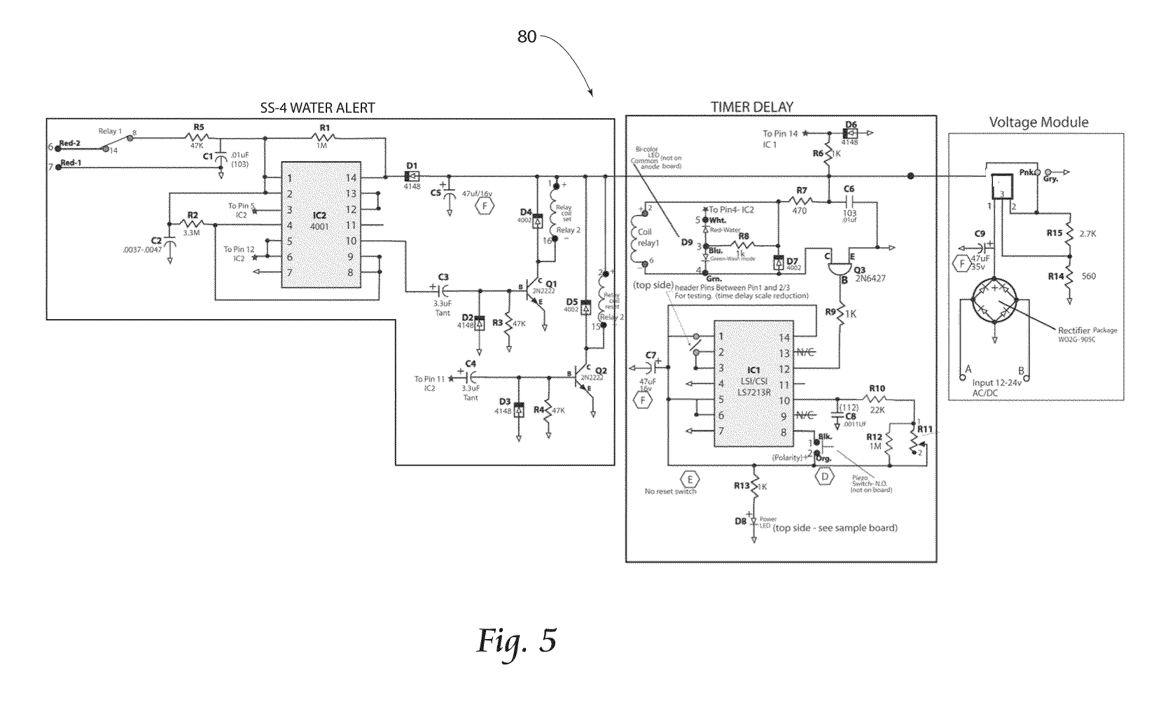

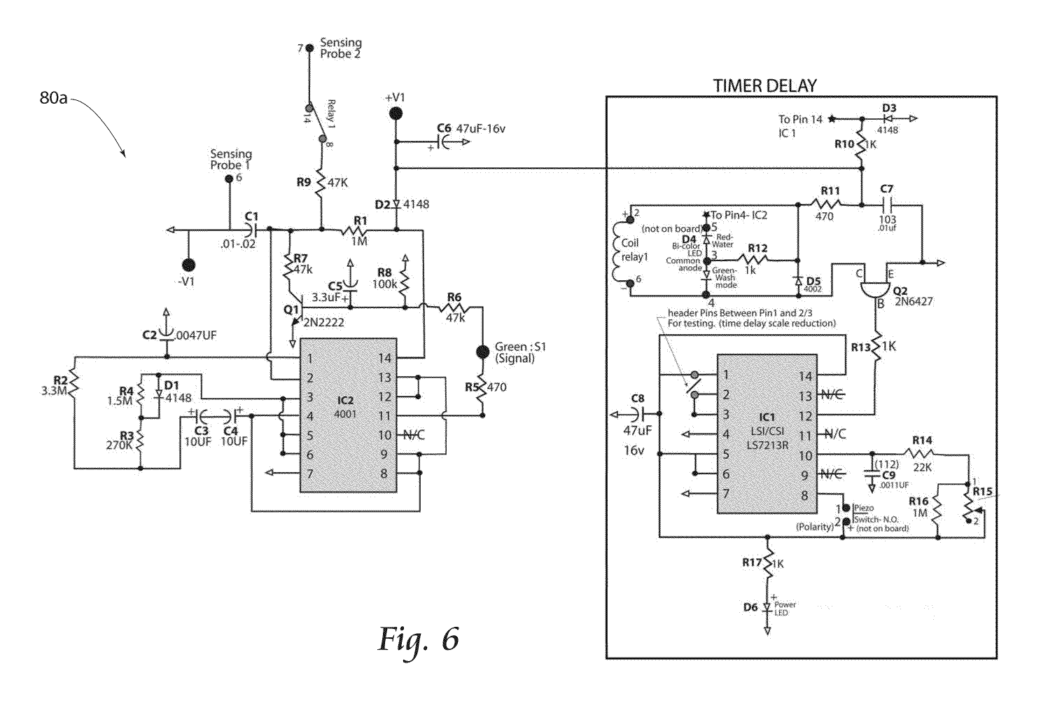

Now referring to FIG. 2, it can be seen that the cover 30 has been removed from the housing 20. Within housing 20 is located the conductive fluid detecting circuit, shown generally at reference numeral 80. Circuit 80 is depicted in detail in FIGS. 5 and 6. The circuit 80 includes an adjustable timer 90. The length of the deactivation period or wash down mode is set by adjusting the timer 90. In the preferred embodiment, the time period can be set between 15 minutes and 2 hours. Also within the housing 20 is a connector block 92. Preselected terminals on connector block 92 receive the power input required for the conductive fluid leak detector 10 and also connect to the signal wires which send an alarm signal to the building maintenance system and/or security system when the presence of conductive fluid is detected. The connector block 92 is coupled to the circuit 80.

FIG. 2 also depicts two additional openings 28 in housing 20 which are sized to receive a conduit (not shown). The conduit houses two pairs of electrical wires 94 and 96. The electrical wires 94 and 96 pass from the conduit into the housing 20 and connect to preselected terminals on connector block 92. Electrical wires 94 supply power to the circuit 80 and electrical wires 96 carry the output signal generated when an alarm is triggered. The conduit is connected to one of the openings 28, depending upon the installation of the device 10. The wires 94 and 96 pass through the conduit and connect to the connector block 92 as described. The unused conduit opening 28 is plugged with a conventional plug (not shown) that provides a fluid tight and tamper resistant seal between the plug and housing 20.

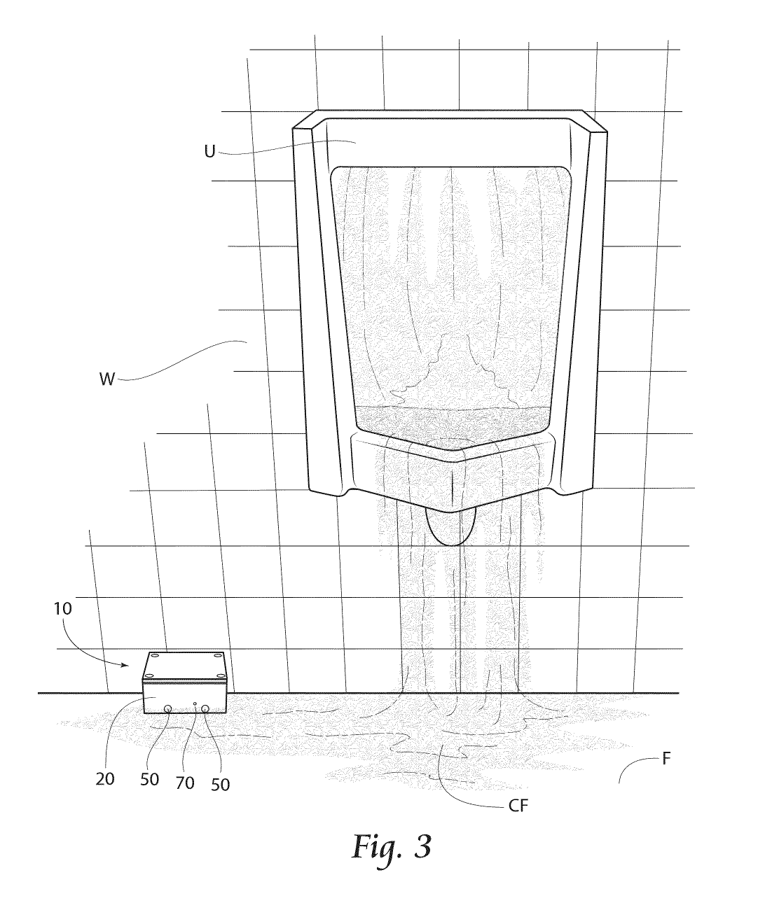

As shown in FIG. 3, the conductive fluid leak detector 10 may be mounted on the floor of a room or area where it is desirable to monitor for a conductive fluid leak. Typically, the location is near or adjacent to a conductive fluid utilizing appliance such as a toilet, water heater, dishwasher, parts washer, etc. Specifically in FIG. 3, the device 10 is shown mounted to the floor F of a restroom adjacent a urinal U. FIG. 3 further depicts an “overflow” condition whereby conductive fluid CF such as water is not properly draining through the urinal drain and is instead overflowing onto the restroom floor F. In addition to creating a safety hazard and unsanitary condition, if not quickly discovered the overflowing conductive fluid CF will likely cause damage to the restroom as well as adjacent areas in the building. The housing 20 is secured to the floor F or wall W with suitable fasteners (not shown). A conduit is connected to either opening 28 for providing electrical power to the circuit 80 and for housing the signal wires connected to an alarm panel, building management system and/or relay coupled to an electronic conductive fluid control valve. Ideally, the conduit is not visible or exposed in the room or environment where the detector 10 is mounted (as shown in FIG. 3). However, the conduit may be exposed if necessary for the installation.

The schematic circuit diagram shown in FIG. 5 depicts the preferred circuit 80 when the conductive fluid leak detector 10 is connected to a traditional security system or building management system. Power is supplied by the power source or supply 100 to the voltage module. The switch 60 and visual indicator 70 are coupled to the timer delay. An output signal is sent by the circuit 80 upon detection of conductive fluid by the sensors 50.

The schematic shown in FIG. 6 depicts an alternate circuit 80a. This circuit 80a is coupled to a specific monitoring panel, such as the 2100 Series monitoring panel manufactured by Dorlen Products, Inc., Milwaukee, Wis. By utilizing this panel (or an equivalent thereof) a user can test the detector 10 from the monitoring panel to insure the detector is working properly.

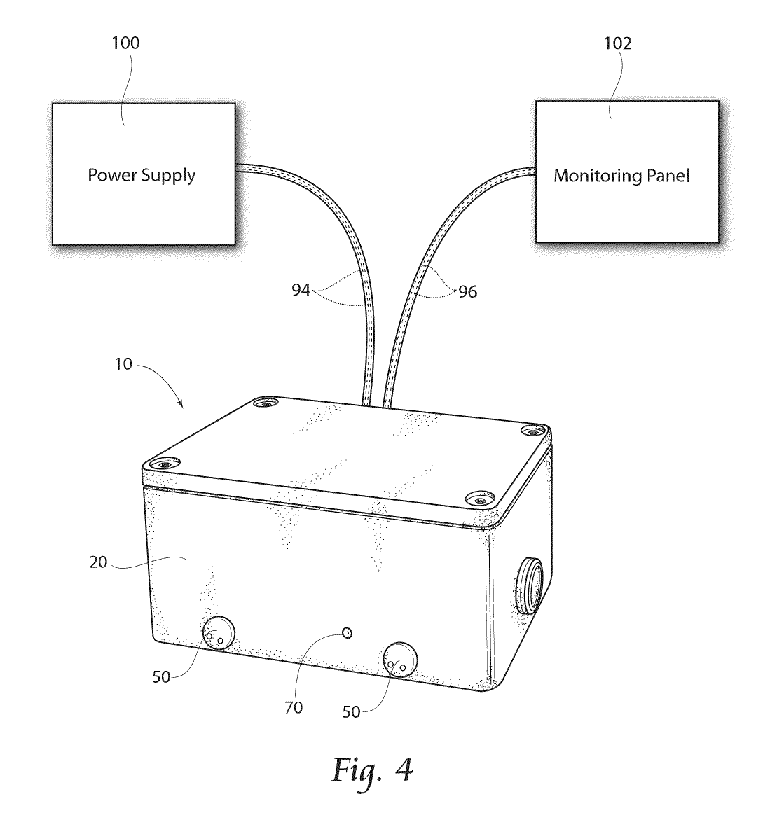

Once installed and in use, the device 10 begins monitoring for the presence of conductive fluid. As shown in FIG. 4, when power has been connected to the circuit via a power source or supply 100, an internal visual indicator 82 (see FIG. 2) displays a predetermined color, green for example. If conductive fluid bridges both probes 50, a conductive fluid leak is sensed by the detector 10. The external visual indicator 70 will illuminate (red for example) and the circuit 80's internal relay contacts will transfer. The detector 10 sends an output signal through wires 96 to the security system or building monitoring system 102 to which the detector 10 is connected. Once the conductive fluid is removed, the device 10 will automatically reset.

When a janitor or cleaning personnel desires to clean the area immediately surrounding the device 10, there is a high likelihood that the cleaning apparatus, such as a mop for example, and/or the cleaning solution will contact the probes 50 and trigger an alarm. While this would be a false alarm, the system or systems to which the device 10 is connected have no way of discerning what was the cause of the alarm. Accordingly, the present invention 10 is equipped with a wash down mode of operation. This allows the area around the device 10 to be cleaned with conductive fluid or a conductive fluid-based cleaning solution without activating an alarm. The wash down mode is activated by simply touching the piezo electronic switch 60 on the housing 20. As described above, the switch has no moving parts and is touch sensitive. The external visual indicator 70 will illuminate in a predetermined color, green for example, to indicate that the device 10 is now in the wash down mode. The device 10 will remain in the wash down mode for the period of time that was selected and entered at the timer 90. In the preferred embodiment, this time period is between 15 minutes and 2 hours. During this time period, the sensing circuit 80/80a is deactivated and no alarm signals are sent by the device 10. Once the wash down mode time period expires, the sensing circuit 80/80a is re-activated and the device 10 returns to its normal sensing operation.

The foregoing is considered as illustrative only of the principles of the invention. Furthermore, since numerous modifications and changes will readily occur to those skilled in the art, it is not desired to limit the invention to the exact construction and operation shown and described. While the preferred embodiment has been described, the details may be changed without departing from the invention, which is defined by the claims.

I claim:

1. A conductive fluid leak detector comprising:
a housing;
at least one fluid sensing probe, said probe being affixed to said housing;
a fluid sensing circuit, said at least one probe being coupled to said circuit;
a switch, said switch affixed to said housing and coupled to said circuit;
a power supply, said power supply coupled to said circuit; and
said circuit further comprising a timer whereby when said switch is activated, said fluid sensing circuit is deactivated for a predetermined period of time.

2. The conductive fluid leak detector of claim 1 further comprising an indicator light, said indicator light being affixed to said housing and coupled to said circuit.

3. The conductive fluid leak detector of claim 1 further comprising a detector output, said detector output being coupled to said circuit and sending a signal upon said at least one sensing probe sensing a conductive fluid unless said fluid sensing circuit has been deactivated for said predetermined period of time.

4. The conductive fluid leak detector of claim 1 further comprising a pair of probes.

5. The conductive fluid leak detector of claim 1 wherein said housing is of tamper-resistant construction.

6. The conductive fluid leak detector of claim 1 wherein said at least one probe is of tamper-resistant construction.

7. The conductive fluid leak detector of claim 1 wherein said switch is of tamper-resistant construction.

8. The conductive fluid leak detector of claim 1 wherein said switch is a piezo electronic switch.

9. The conductive fluid leak detector of claim 3 wherein said detector output is coupled to a device from the group consisting of an alarm system, a security system, a building management system and a monitoring system.

10. The conductive fluid leak detector of claim 1 wherein said predetermined period of time is adjustable.

11. A conductive fluid leak detector comprising:
a housing;
at least one conductive fluid sensing probe, said probe affixed to said housing;
a fluid sensing circuit, said circuit contained within said housing and said at least one probe being coupled to said circuit;
a switch, said switch affixed to said housing and coupled to said circuit;
a power supply, said power supply coupled to said circuit;
said fluid sensing circuit comprising a timer; and
said fluid sensing circuit further comprising an activation mode and a deactivation mode whereby switching said switch triggers said circuit from said activation mode to said deactivation mode and ending said timer triggers said circuit from said deactivation mode to said activation mode.

12. The conductive fluid leak detector of claim 11 further comprising an indicator light, said indicator light being affixed to said housing and coupled to said circuit.

13. The conductive fluid leak detector of claim 11 further comprising a detector output, said detector output being coupled to said circuit and sending a signal upon said at least one sensing probe sensing a conductive fluid unless said fluid sensing circuit is in said deactivation mode.

14. The conductive fluid leak detector of claim 11 further comprising a pair of probes.

15. The conductive fluid leak detector of claim 11 wherein said housing is of tamper-resistant construction.

16. The conductive fluid leak detector of claim 11 wherein said at least one probe is of tamper-resistant construction.

17. The conductive fluid leak detector of claim 11 wherein said switch is of tamper-resistant construction.

18. The conductive fluid leak detector of claim 11 wherein said switch is a piezo electronic switch.

19. The conductive fluid leak detector of claim 13 wherein said detector output is coupled to a device from the group consisting of an alarm system, a security system, a building management system and a monitoring system.

20. The conductive fluid leak detector of claim 11 wherein said timer is adjustable.
